(19) United States
(12) Patent Application Publication
(10) Pub. No.: US 2014/0305471 A1
(43) Pub. Date: Oct. 16, 2014

(54) REDUCED CONSUMPTIONS STAND ALONE RINSE TOOL HAVING SELF-CONTAINED CLOSED-LOOP FLUID CIRCUIT, AND METHOD OF RINSING SUBSTRATES USING THE SAME

(71) Applicants: Ismail Kashkoush, Orefield, PA (US); Dennis Nemeth, Nazareth, PA (US); Gim-Syang Chen, Allentown, PA (US)

(72) Inventors: Ismail Kashkoush, Orefield, PA (US); Dennis Nemeth, Nazareth, PA (US); Gim-Syang Chen, Allentown, PA (US)

(73) Assignee: AKRION SYSTEMS LLC, Allentown, PA (US)

(21) Appl. No.: 14/239,709

(22) PCT Filed: Aug. 20, 2012
(86) PCT No.: PCT/US12/51630

§ 371 Date: Jun. 2, 2014

Related U.S. Application Data
(60) Provisional application No. 61/525,407, filed on Aug. 19, 2011.

(51) Int. Cl. H01L 21/67

(52) U.S. Cl. CPC H01L 21/67051
USPC 134/10; 134/109; 134/56 R

(57) ABSTRACT

A system and method for rinsing substrates. In one embodiment, method comprises: a) providing a fixed volume of a rinse fluid in a rinse tool comprising a closed-loop fluid-circuit comprising a rinse tank, a deionizer, a pump, and a recirculation line fluidly coupled to an outlet of the rinse tank and an inlet of the rinse tank; and b) performing a plurality of rinse cycles in the rinse tool, each of the plurality of rinse cycles including: b-1) positioning a batch of substrates in the rinse tank; b-2) circulating the fixed volume of the rinse fluid through the fluid circuit for a rinse time, wherein during said circulation the rinse fluid contacts the batch of substrates, thereby becoming ionically contaminated rinse fluid, the deionizer removing ionic impurities from the ionically contaminated rinse fluid to produce deionized rinse fluid; and b-3) removing the batch of substrates from the rinse tank.

### CROSS-REFERENCE TO RELATED PATENT APPLICATIONS

The present application is a U.S. national stage application under 35 U.S.C. §371 of PCT Application No. PCT/US12/51630, filed on Aug. 20, 2012, which claims the benefit of U.S. Provisional Patent Application Ser. No. 61/525,407, filed Aug. 19, 2011, the entireties of which are hereby incorporated herein by reference.

### FIELD OF THE INVENTION

The present invention relates generally to the field of substrate processing, and specifically to systems and methods of rinsing substrates, such as semiconductor wafers and/or solar panels, with pure rinse fluid.

### BACKGROUND OF THE INVENTION

In the semiconductor industry, effectively removing all impurities (particulate, fluidic, and ionic) from the surface of a wafer or substrate is of utmost importance. If impurities are left on the surface of a wafer, the wafer will not operate properly. Furthermore, removing impurities from semiconductor wafers during the manufacturing process is a critical requirement to producing quality profitable wafers. Many different systems and methods have been developed over the years to remove impurities from semiconductor wafers.

During the manufacturing process, semiconductor wafers may go through hundreds of processing steps. One of the most frequently performed of those processes is wafer cleaning. In a wafer cleaning process, impurities, such as organic compounds, metallic impurities, micro-particles and chemicals/ionic species, are removed from the surface of the wafer. However, most wafer cleaning processes consume extremely large quantities of water. In fact, a large portion of the product cost for fabricating the integrated circuits lies in the purchase of pure water.

In recent years, increasing attention has focused on the environmental impact of semiconductor manufacturing. Once considered a clean, high-tech industry, wafer fabrication facilities now are being viewed more and more as chemical processing plants that consume large volumes of water and hazardous chemicals. As the industry continues its historic expansion, water conservation initiatives are also becoming realities.

Although the industry is making significant progress in chemical conservation, water consumption has continued to increase at an alarming rate. It is, therefore, an object of the present invention to provide a system and method to clean/rinse semiconductor wafer (and other substrates) that minimizes rinse fluid consumption.

Conventional wafer processing uses de-ionized water (hereinafter, “DIW”) to rinse off impurities from wafers surfaces. The contaminated effluent is sent to drain for central waste treatment inside the semiconductor fabrication facility (hereinafter, “fab”), as it is considered still hazardous waste. These large volumes of rinse water require large volumes of waste treatment water to neutralize the impurities/hazardous wastes (acids and bases). For this reason, some advanced systems reclaim partial volumes of this water (last portion of the cycle). However, these volumes of water still require large and expensive polishing and deionization units to handle different ions and cations.

Thus, a need exists for a system and method for deionizing/cleaning rinse water without the need for large, sophisticated reclaim systems that are costly and occupy an enormous amount of space. A need also exists for a rinsing system and method for deionizing/cleaning rinse water that conserves water during the manufacture of semiconductor wafers in the fab.

### SUMMARY OF THE INVENTION

In one embodiment, the invention can be a method of rinsing substrates comprising: a) providing a fixed volume of a rinse fluid in a stand-alone rinse tool comprising a closed-loop fluid-circuit comprising a rinse tank, a deionizer, a pump, and a recirculation line fluidly coupled to an outlet of the rinse tank and an inlet of the rinse tank; and b) performing a plurality of rinse cycles in the stand-alone rinse tool using the fixed volume of the rinse fluid, wherein each of the plurality of rinse cycles comprises: b-1) positioning a batch of substrates comprising ionic impurities in the rinse tank; b-2) circulating the fixed volume of the rinse fluid provided in step a) through the closed-loop fluid circuit for a rinse time sufficient to remove the ionic impurities from the batch of substrates, wherein during said circulation the rinse fluid contacts the batch of substrates, thereby becoming ionically contaminated rinse fluid that flows through the deionizer, the deionizer removing ionic impurities from the ionically contaminated rinse fluid to produce deionized rinse fluid that is introduced back into the rinse tank; and b-3) removing the batch of substrates from the rinse tank upon expiration of the rinse time.

In another embodiment, the invention can be a stand-alone rinse tool comprising: a closed-loop fluid-circuit comprising, in operable coupling, a rinse tank, a deionizer, a pump, and a recirculation line fluidly coupled to an outlet of the rinse tank and an inlet of the rinse tank; a housing containing the closed-loop fluid circuit; a fixed volume of a rinse fluid contained in the closed-loop fluid circuit; and a controller configured to perform a plurality of rinse cycles using the fixed volume of the rinse fluid in the closed-loop fluid circuit, wherein for each of the rinse cycles, the controller is further configured to circulate the fixed volume of the rinse fluid through the closed-loop fluid circuit for a rinse time sufficient to remove ionic impurities from a batch of substrates, wherein during said circulation the rinse fluid contacts the batch of substrates, thereby becoming ionically contaminated rinse fluid that flows through the deionizer, the deionizer removing ionic impurities from the ionically contaminated rinse fluid to produce deionized rinse fluid that is introduced back into the rinse tank.

In yet another embodiment, the invention can be a method of rinsing substrates comprising: a) providing a stand-alone rinse tool comprising a closed-loop fluid-circuit comprising a rinse tank, a deionizer, a pump, and a recirculation line fluidly coupled to an outlet of the rinse tank and an inlet of the rinse tank; b) during an initial set-up procedure, supplying a fixed volume of a rinse fluid into the closed-loop fluid circuit; and c) performing a plurality of rinse cycles in the stand-alone rinse tool using the fixed volume of the rinse fluid, wherein each of the plurality of rinse cycles comprises: c-1) positioning a batch of substrates comprising ionic impurities in the rinse tank; c-2) circulating the fixed volume of the rinse fluid provided in step b) through the closed-loop fluid circuit for a rinse time sufficient to remove the ionic impurities from the batch of substrates, wherein during said circulation the rinse fluid contacts the batch of substrates, thereby becoming ionically contaminated rinse fluid that flows through the deionizer, the deionizer removing ionic impurities from the ionically contaminated rinse fluid to produce deionized rinse fluid that is introduced back into the rinse tank; and c-3) removing the batch of substrates from the rinse tank upon expiration of the rinse time; wherein subsequent to step b), substantially no additional rinse fluid is introduced into the closed-loop fluid circuit.

Further areas of applicability of the present invention will become apparent from the detailed description provided hereinafter. It should be understood that the detailed description and specific examples, while indicating the preferred embodiment of the invention, are intended for purposes of illustration only and are not intended to limit the scope of the invention.

### BRIEF DESCRIPTION OF THE DRAWINGS

The present invention will become more fully understood from the detailed description and the accompanying drawings, wherein

FIG. 1 is a graph illustrating the characteristics of deionized water after a conventional rinse cycle;

FIG. 2 is a graph illustrating the rinse characteristics using an ion exchanger in accordance with an embodiment of the present invention;

FIG. 3 is a graph illustrating the cyclical performance of an ion exchanger in accordance with an embodiment of the present invention; and

FIG. 4 is a schematic of a stand-alone rinse tool according to an embodiment of the present invention.

### DETAILED DESCRIPTION OF THE INVENTION

The following description of the preferred embodiment(s) is merely exemplary in nature and is in no way intended to limit the invention, its application, or uses.

The description of illustrative embodiments according to principles of the present invention is intended to be read in connection with the accompanying drawings, which are to be considered part of the entire written description. In the description of the exemplary embodiments of the invention disclosed herein, any reference to direction or orientation is merely intended for convenience of description and is not intended in any way to limit the scope of the present invention. Relative terms such as “lower,” “upper,” “horizontal,” “vertical,” “above,” “below,” “up,” “down,” “left,” “right,” “top,” “bottom,” “front” and “rear” as well as derivatives thereof (e.g., “horizontally,” “downwardly,” “upwardly,” etc.) should be construed to refer to the orientation as then described or as shown in the drawing under discussion. These relative terms are for convenience of description only and do not require that the apparatus be constructed or operated in a particular orientation unless explicitly indicated as such. Terms such as “attached,” “affixed,” “connected,” “coupled,” “interconnected,” “secured” and similar refer to a relationship wherein structures are secured or attached to one another either directly or indirectly through intervening structures, as well as both movable or rigid attachments or relationships, unless expressly described otherwise. Moreover, the features and benefits of the invention are described by reference to the exemplary embodiments illustrated herein. Accordingly, the invention expressly should not be limited to such exemplary embodiments, even if indicated as being preferred. The discussion herein describes and illustrates some possible non-limiting combinations of features that may exist alone or in other combinations of features. The scope of the invention is defined by the claims appended hereto.

For purposes of this invention, it is to be understood that the term substrate is intended to mean any solid substance onto which a layer of another substance is applied and that is used in the solar or semiconductor industries. This includes, without limitation, silicon wafers, glass substrates, fiber optic substrates, fused quartz, fused silica, epitaxial silicon, raw wafers, solar cells, medical devices, disks and heads, flat panel displays, microelectronic masks, and other applications requiring high purity fluids for processing. The terms substrate and wafer may be used interchangeably throughout the description herein. Furthermore, it should be understood that the invention is not limited to any particular type of substrate and the methods described herein may be used for the preparation and/or drying of any flat article. Finally, as used herein the term “batch of substrates” is intended to include batches that include only a single substrate. Thus, inventive rinse methods and inventive rinse tools described herein can be adapted to be used in, or as, non-immersion single wafer processing tools, such as the non-immersion single wafer tool structure and cleaning methods disclosed in U.S. Pat. No. 6,039,059, issued Mar. 21, 2000, which is hereby incorporated by reference. With that said, the invention will be described herein in reference to batch processing in which a plurality of substrates are processed simultaneously in the same tool, which are typically transported form tool to tool in a carrier basket (also known as a wafer basket).

By way of background, in a typical semiconductor processing operation, the wafer undergoes multiple chemical treatment steps in which the wafer is etched or stripped. Upon completion of these steps, the chemical that etches the wafer must be completely removed from the surface of the wafer in order to stop the chemical reaction that produces the etching effect and take away chemical residues. When taken out of a chemical bath, approximately 50-200 ml of the chemical medium is carried over with each batch of wafers. Thus, at this time chemistry is still covering the wafer surface, in particular within recess structures of the topology, which results in continuation of the chemical process outside the bath or chemical processing tank. Thus, an immediate replacement or removal of the active chemical is needed in order to prevent over etching and to effectively remove loosely attached particles. This is achieved by high efficiency rinsing.

During rinsing after the chemical steps, the objectives include quickly and effectively stopping the chemical reaction on the surface of the wafers, fully removing the chemical and contaminant residues from the wafer which are carried over from the chemical tank without any impact on the wafer surface and taking off particulates from the wafer surface before the next chemical step or drying.

There are several different conventional rinse methods that remove the chemistry and particulates from the wafer. The first is overflow rinsing wherein the wafer or wafers are immersed into a rinse bath with a continuous introduction of water from the bottom of the tank and an overflow at the top rim of the tank. The second is spray rinsing where ultra-pure deionized water (i.e., DIW) is dispensed through spray nozzles directly onto the wafer surface at variable flow pressures or temperatures in a single pass mode. The third is a quick dump rinse which consists of placing the wafer into an overflow rinse tank, dumping the ultra pure water in a very fast manner (quick dump) and refilling the tank by spray and/or fill from the bottom of the tank. This quick dump rinse can be repeated as necessary or desired.

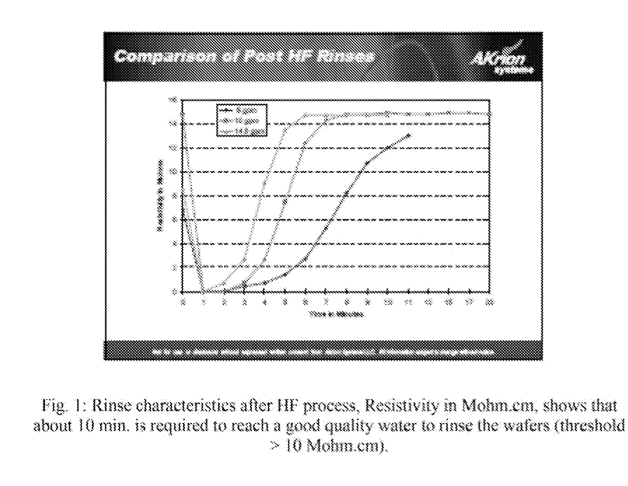

In some conventional rinse cycles (see FIG. 1), the wafer is positioned in the rinse tank and subjected to three quick dump rinses followed by five cycles of overflow cascades. This process takes approximately ten minutes to complete. At a rate of 10 gpm, the water consumption is 100 gallons per cycle. This volume of water will be either sent to a facility water treatment system or a portion of it will be reclaimed at a central reclaim station. FIG. 1 illustrates the characteristics (i.e., resistivity) of the water used in the rinse cycle. Thus, according to FIG. 1 it takes approximately ten minutes of rinsing for the water used in the rinse cycle to have a high enough resistivity to be reused without needing to be reclaimed at a central reclaim station. In other words, it takes approximately ten minutes before the chemical residues on the wafer have subsided enough so that the rinse water post application to the wafer is clean and of sufficient quality for reuse (wherein quality and clean water are defined as having a resistivity greater than 10 Mohm-cm in the exemplified graph). Prior to that time, the water must be sent to the facility water treatment system because it contains too many ionic impurities and too much chemical residue. This is a costly and wasteful expenditure.

Using these conventional rinse methodologies, the ultra-pure water will remove the chemistry and the particulates that are carried over from prior processing steps from the wafer. However, the ultra-pure water will then be contaminated with the chemistry and/or particulates. Thus, this contaminated water can either be disposed of or recycled by flowing the contaminated water into a large and sophisticated water reclaim station that cleans the water of contaminants so that it can be reused.

The present invention speeds up the process of producing ultra-pure water after the wafer is rinsed and negates the need for the centralized reclaim station. The present invention also has the potential to result in nearly zero net water consumption. In the present invention, ions present in the water used to rinse the wafer are extracted directly in the stand-alone rinse tool and, in certain instances, directly at the rinse tank (i.e., both of which are considered at the point of use). Thus, the present invention eliminates the possibility of cross contamination that requires the large-size deionization systems. In other words, in conventional methods water from several different rinse tanks are combined into a large deionization system, which then removes all of the combined ionic impurities. By extracting the ions directly in the stand-alone rinse tool, the need for these large deionization systems is negated. Thus, utilizing the present invention, the deionized water can be reused immediately without the need for large or long plumbing loops, which results in a substantially reduced operating cost. Furthermore, the stand-alone rinse tool of the present invention offers environmental advantages by saving enormous volumes of water on a regular basis.

The present invention uses ion exchangers positioned directly within or very near to the rinse tank (i.e., just external to and adjacent the drain) to extract the ionic impurities brought to the rinse tank from the previous process tank in the form of drag out. In certain embodiments, a mixed resin bed is positioned within the rinse tank to extract the ionic impurities from the rinse water. The mixed resin bed, in certain embodiments, comprises both acid cation exchange resins and base anion exchange resins for purifying the rinse water after it is applied to the surface of the wafer. Examples of ionic impurities that may be brought to the rinse tank from the process tank and removed via the mixed resin bed (i.e., ion exchanger) include HCl, HF, KOH, NH₄OH, NaOH, H2SO₄, H₃PO₄.

According to the invention, wafers will be brought to the inventive stand-alone rinse tool. The stand-alone rinse tool is a self-cleaning and self-contained tool. Thus, the stand-alone rinse tool comprises a self-contained closed-loop fluid circuit that requires no holding tank for containing additional deionized/pure water during a rinse cycle. In this manner, the stand-alone rinse tool can use purely recirculated water from the beginning to the end of each of the rinse cycles. In other words, using the inventive rinse method and stand-alone rinse tool, the wafer can be placed in the rinse tank and subjected to deionized water. The deionized water will contact the wafer surface (either via spray or immersion) and then contact or be subjected to the deionizer, which can be an ion-exchanger in the form of a mixed resin bed. The mixed resin bed will remove ionic impurities from the rinse water, and the rinse water will then flow directly back into the rinse tank and be reapplied to the wafer for further rinsing/cleaning. In other words, the present invention negates the need for costly water cleaning and reclaim stations by self-cleaning the deionized rinse water for automatic reuse in a single, self-contained rinse tool.

Of course, although the invention is described as a stand-alone rinse tool having no holding tank (in addition to the rinse tank), in certain embodiments, the stand-alone rinse tool can be fluidly coupled to a re-feed line so that additional deionized water can be fed into the closed-loop fluid circuit (which includes the rinse tank) in order to account for evaporative loss and drag out. Thus, the rinse tank may include a level sensor connected to a processor/controller so that the addition of fresh deionized water from the re-feed line can be supplied automatically to the rinse tank as necessary. Furthermore, an occasional flush can take place whereby the deionized water is removed from the closed-loop fluid circuit of the stand-alone rinse tool and replaced with a fresh amount of the deionized water.

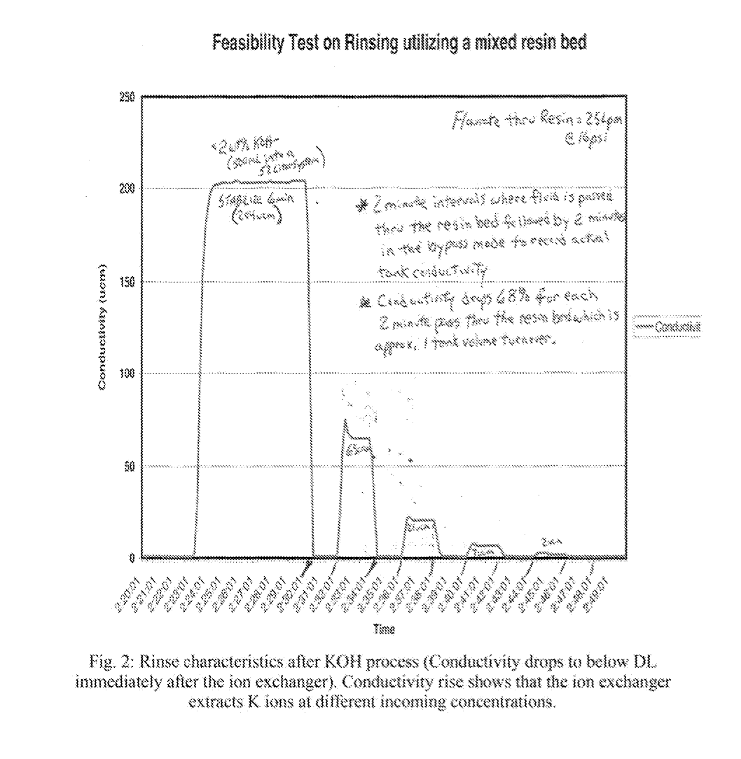

As described above, the stand-alone rinse tool will include a deionizer, which can be in the form of an ion exchanger that will extract ions out at the point of use. Although the invention is described herein as being a deionizer within the rinse tank, in certain embodiments there may be an ion filter (i.e., ion exchanger/water purifier) and a particle filter, such as a filter bank. An example of a combined filtration system is disclosed in U.S. Pat. No. 7,311,847, issued Dec. 25, 2007, the disclosure of which regarding combined filtration means and the control thereof is incorporated herein by reference. The advantage of the present invention is to eliminate the need for large and sophisticated reclaim stations, which are costly and occupy a great deal of space. Importantly, the present invention has the potential to use near zero net water consumption. Referring to FIG. 2, the concentration drops from 200 uS/cm (or approx. 100 ppm K+) to below the detectable level (BDL) after a mere two minutes. Similar behavior was observed when 500 ml of 1% HF (fluoride ions F−) and 1%. HCl (chloride ions Cl−) were introduced into the above-described rinse tank.

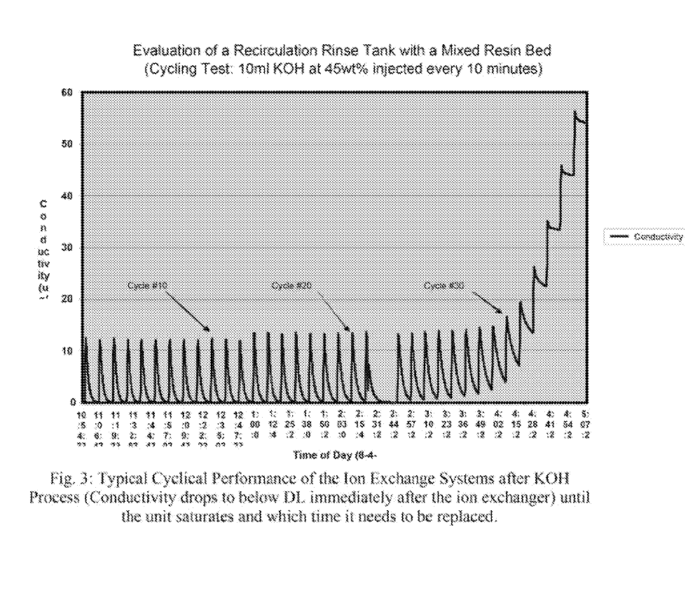

FIG. 3 exemplifies an evaluation of a stand-alone rinse tool having a closed-loop fluid circuit having a mixed resin bed disposed therein. The rinse tank with a mixed resin bed was tested with 10 ml of KOH at 45 wt % injected every ten minutes in order to determine the cyclical performance of the mixed resin bed (ion exchanger) over time after a KOH processing step. FIG. 3 illustrates the conductivity of the rinse/deionized water dropping to below the detectable limit immediately after contacting the ion exchanger, until the ion exchanger saturates, upon which time the ion exchanger must be replaced. In FIG. 3, the ion exchanger is shown to saturate at approximately cycle number 30.

It should be understood that the above-described invention can be used with an overflow rinsing tank, a spray rinsing tank or a quick dump rinsing tank. With an overflow rinsing tank, the water that flows over the top edge of the tank will flow through an ion exchanger and immediately be reintroduced into the bottom of the tank. With a spray rinsing tank, the water will flow through an ion exchanger after being sprayed onto the wafer surface, and will then be reintroduced into the tank through the spray system. In a quick dump rinsing tank, the water that is dumped will flow through an ion exchanger and then be reintroduced into the tank through either a spray and/or fill from the bottom of the tank.

Thus, in each of these rinse tank systems, the water will be deionized upon flowing through an ion exchanger so that the water can be reused without treatment at a reclaim station or treatment facility. The same water can continue to be used for an unlimited number of cycles as long as the ion exchanger is replaced on an as-needed basis as described herein above. As a result, the above-described system is environmentally friendly and results in approximately zero net water consumption (near zero only due to the need for replacement due to evaporative loss).

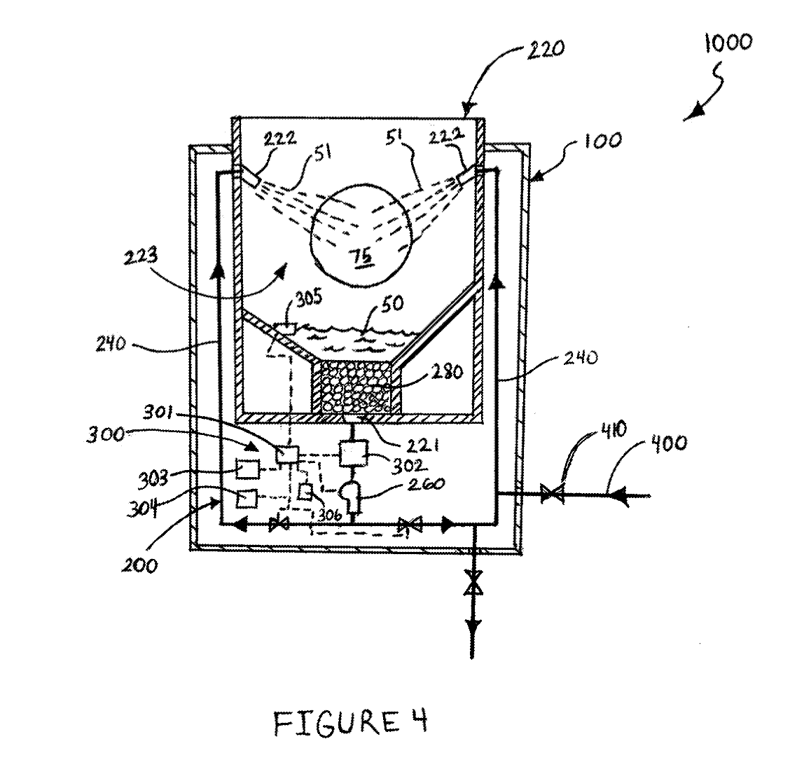

Referring now to FIG. 4, a stand-alone rinse tool 1000 according to an embodiment of the present invention is illustrated. As mentioned above, the stand-alone rinse tool 1000 is designed to a be a self-contained rinsing station that, after the initial provision of a fixed volume of rinse fluid 50, utilizes substantially zero rinse fluid consumption (with the exception that minimal amounts of rinse fluid 50 may be lost due to evaporation and drag out). Thus, the stand-alone rinse tool 1000 can perform a large number of consecutive rinse cycles for batches of substrates 75 utilizing only that fixed volume of rinse water that was supplied during the initial start-up. In certain embodiments, an unlimited number of rinse cycles can be performed using the stand-alone rinse tool 1000 over the lifetime of the tool, with the only addition of rinse fluid being negligible amounts to compensate for evaporation and drag out.

The stand-alone rinse tool 1000 generally comprises a housing 100, a closed-loop fluid circuit 200 and a control sub-system 300. The closed-loop fluid circuit 200 comprises, in operable and fluid coupling, a rinse tank 220, a recirculation line 240, a pump 260 operably coupled to the recirculation line 240, and a deionizer 280. The recirculation line 240 is fluidly coupled to and extends from an outlet 221 of the rinse tank 220 to an inlet(s) 222 of the rinse tank 220. Thus, the recirculation line 240 transports rinse fluid 50 exiting the rinse tank 229 via the outlet 221 back into the rinse tank 220 via the inlet(s) 222.

In the exemplified embodiment, the rinse tank 220 is spray rinse tank. Thus, the inlets 222 are one or more spray nozzles that introduce the re-circulated rinse fluid 50 back into the rinse tank 200 as a spray 51 that contacts a batch of substrates 75 that are supported within the rinsing chamber 223 of the rinse tank 220. In certain embodiments, a lid may be coupled to the rinse tank 220 that substantially encloses the rinse chamber 223 when closed. While the rinse tank 220 is exemplified as spray rinse tank in FIG. 4, it is to be understood that the rinse tank 220, in other embodiments, can be an overflow rinse tank, a quick dump rinse tank, or a single-wafer non-immersion rinse chamber. In such embodiments, the inlet 22 may be a simple opening and/or conduit that delivers the rinse fluid 50 back into the rinse chamber 223 in which the substrates 75 are supported for contact therewith. The application of the rinse fluid 50 to the substrates 75 can be effectuated by any means known in the art, such as cascade rinsing, spray nozzles, sparger plates, nozzles that apply thin layers of fluid on the wafer, etc. Moreover, in some embodiments, a source of megasonic energy can be coupled to rinse tank 220 to supply acoustical energy to the substrates 75 during rinsing.

The closed-loop fluid circuit 200 also comprises the deionizer 280, which in the exemplified embodiment is a mixed bed ion-exchanger that is located within the rinse tank 220 itself. The deionizer 280, in alternate embodiments, can be an ion filter, ion extractor or other device capable of removing ionic impurities from the rinse fluid 50 as the rinse fluid 50 passes therethrough. Moreover, while the deionizer 280 is located within the rinse tank 220, at a location adjacent to and upstream of the drain 221, in the exemplified embodiment, in other embodiments the deionizer 280 may be located outside of the rinse tank 220. For example the deionizer 280 may be located adjacent to but downstream of the drain 221. In still other embodiments, the deionizer 280 can be fluidly coupled to any point of the recirculation line 240 so that rinse fluid 50 exiting the rinse tank 220 must pass through the deionizer 280 prior to being introduced back into the rinse tank 220 via the inlet(s) 222.

In the closed-loop fluid circuit 220, the deionizer 280 is located downstream of the location where the rinse fluid 50 contacts the substrates 75. When the rinse fluid 50 is circulated through the closed-loop fluid circuit 200 by the pump 260, the rinse fluid contacts the substrates 75, thereby removing and carrying away ionic impurities from the substrates 75. As a result, the rinse fluid 50, after contacting the substrates 75, becomes ionically contaminated rinse fluid 50 that gathers in the bottom of the rinse tank 220 as a bath. This ionically contaminated rinse fluid 50 then flows through the deionizer 280, which removes the ionic impurities from the ionically contaminated rinse fluid 50, thereby discharging deionized rinse fluid 50 as its effluent that is introduced back into the rinse tank 220. As used herein, the deionized rinse fluid 50 exiting the deionizer does not, in all embodiments, have to be completely deionized. Rather, it is sufficient that the rinse fluid 50 exit the deionizer with less ionic impurities than that with which it entered.

The closed-loop fluid circuit 200 also comprises valves 250, 251 operably and fluidly coupled to the recirculation line 240. The valves 250, 251 can be manipulated as necessary to prohibit or allow flow of the rinse fluid 50 through the closed-loop fluid circuit 200 as desired. The closed-loop fluid circuit 200, in the exemplified embodiment, is contained entirely within the housing 100. Of course, in certain other embodiments, a small portion of the closed-loop fluid circuit 200 may not be contained within the housing 100. Moreover, in certain other embodiments, the stand-alone rinse tool 1000 may not include a separate housing 100 in addition to the rinse tank 220. Thus, the body of the rinse tank 220 itself can be considered part of the housing 100 (or the entire housing 100). Whether or not the closed-loop fluid circuit 200 is contained within the housing 100, the entirety of the closed-loop fluid circuit 200 is sufficiently compact so that it can be considered point-of-use in its entirety in certain embodiments.

The control sub-system 300 comprises, in operable and electrical coupling, a controller 301, an ionic impurity sensor 302, a memory device 303, a notification module 304, a liquid level sensor 305 and a counter 306. The controller 301 is also operably and electrically coupled to the pump 260 and the valves 250, 251 of the closed-loop fluid circuit 200. All components of the control-subsystem 300 are generically illustrated for simplicity. The controller 301 can be a suitable microprocessor based programmable logic controller, personal computer, or the like for process control. The controller 110 includes various input/output ports used to provide connections to the various components of the stand-alone rinse tool 1000 that need to be controlled and/or communicated with during operation. While the memory device 303 and counter 306 are illustrated as being separate from the controller 301, both the memory device 303 and counter 306 can be integrated into the controller 301 if desired. The controller 301 may also include an integrated timer, or a separate timer can be included as part of the control subsystem 300.

The controller 301 is electrically and operably coupled to the ionic impurity sensor 302, the memory device 303, the notification module 304, the liquid level sensor 305, the counter 306, the pump 260 and the valves 250, 251. Thus, the controller 301 can receive and transmit data signals to and from these devices in real time.

The ionic impurity sensor 302 is operably coupled to the recirculation line 240 downstream of the deionizer 280 and upstream of the point where the rinse fluid 50 contacts the substrates 75. The ionic impurity sensor 302 measures ionic impurity levels in the rinse fluid passing therethrough, using such techniques as an Inductively Coupled Plasma Mass Spectroscopy (ICP-MS) or Atomic Absorption Mass Spectroscopy (AA-MS). Acceptable ICP-MS sensors are made by PerkinElmer Models ELAN9000, Elan DRC II, and Elan DRCe.

The liquid level sensor 305 is operably coupled to the rinse tank 220 and measures the liquid level of the rinse fluid 50 that has gathered in the bottom of the rinse tank 220 as the bath. The liquid level sensor 305 can be a float sensor or a laser sensor. During operation of the stand-alone rinse tool 1000, the liquid level sensor 305 will transmit data corresponding to the level of the rinse fluid 50 in the rinse tank 220 (which is also an indirect measure of the volume of the rinse fluid in the closed-loop fluid circuit 200) to the controller 301. As a result, losses of the rinse fluid 50 due to evaporation and drag out can be compensated for over time. Specifically, if the controller 301 receives a measurement signal from the liquid level sensor 305 that indicates that the volume of the rinse fluid 50 in the closed-loop fluid circuit 200 is at or below a predetermined volumetric value, the controller can automatically open valve 410 so that the required volume of additional rinse fluid can be added to the closed-loop fluid circuit 200 via the re-feed line 400. In other embodiments, the controller 301 can merely signal a user that the rinse fluid volume in the stand-alone rinse tool 1000 is low and requires supplemental rinse fluid to be added thereto. This can be done by activating the notification module 304.

The counter 306 counts the number of rinse cycles performed by the stand-alone rinse tool 1000 and communicates this number to the controller 301 for analysis. In certain embodiments, the memory device 303 has stored thereon a predetermined number (N) of rinse cycles that can be performed by the stand-alone rinse tool 1000 before the deionizer 280 becomes saturated. In such an embodiment, upon the controller determining that the N^{th} rinse cycle has been performed (based on the signals received form the counter 306), the controller will generating a signal that the deionizer 280 needs to be replaced, for example by activating the notification module 304. Once the controller 301 determines (or is queued) that the deionizer 280 has been replaced, the counter 306 will be reset to zero and the counting process will begin again. As a result, the deionizer 280 can be replaced prior to the stand-alone rinse tool 1000 failing to properly remove ionic contaminants from a batch of substrates 75. The number (N) of the rinse cycles that can be performed before the deionizer 280 becomes saturated can be determined experimentally by running a plurality of rinse cycles for batches of substrates 75 and measuring the effluent from the deionizer 280 to determine when the deionizer 280 become saturated (see FIG. 3 for example). In other embodiments, the number (N) of the rinse cycles that can be performed before the deionizer 280 becomes saturated can be determined by: estimating an average amount of ionic impurities dragged from a prior process by a batch of substrates 75 that is to be subjected to one of the rinse cycles; and estimating an ionic impurity saturation amount of the deionizer 280. In certain embodiments, the inclusion of the ionic impurity level sensor 302 may negate the need for the counter 306 and the associated processing and memory storage.

The notification module 304 can be an alarm, an electronic display screen or other visual or audio queue. Thus, the controller 301 can signal the user of a condition by activating the alarm and/or creating a visual queue or notification on the electronic display screen. In other embodiments, the controller 301 can signal the user of a condition by shutting down the stand-alone rinse tool 1000 or prohibiting further rinse cycles from being undertaken until the condition is remedied.

During an initial start-up procedure for the stand-alone rinse tool 1000, a fixed volume of the rinse fluid 50 is supplied to the closed-loop fluid circuit 200. In the exemplified embodiment, this can be accomplished by opening valve 410 and allowing the rinse fluid 50 to flow into the closed-loop fluid circuit 200 from the re-feed line 400. The fixed volume of rinse fluid 50 fills the recirculation line 240 and a volume of the rinse chamber 223 of the rinse tank 220. Once the fixed volume of the rinse fluid 50 is supplied to the closed-loop fluid circuit 200, the valve 410 is closed and stand-alone rinse tool 1000 is ready to complete an unlimited amount of rinse cycles using only the fixed amount of the rinse fluid 50 that has been supplied. As can be seen, the closed-loop fluid circuit 200 is free of holding tank containing additional rinse fluid. The closed-loop fluid circuit 200 comprises a free volume (which in the exemplified embodiment is the combined volume of the recirculation and the volume of the process chamber 223 in which the bath of rinse fluid 50 occupies) that is substantially the same as the fixed volume of the rinse fluid 50.

For example, in one embodiment, the fixed volume of the rinse fluid 50 supplied to the closed-loop fluid circuit 200 is fifteen (15) gallons, ten (12) gallons of which are in the bath in the bottom of the process chamber 223 and the remaining three (3) gallons of which are in the recirculation line 240, the deionizer 280 and in the form of spray 51. As will be discussed in greater detail below, this 15 gallon fixed volume of rinse fluid 50 can be used to perform a plurality of rinse cycles for different batches of substrates 75, despite each rinse cycle requiring that up to one-hundred (100) gallons of rinse fluid 50 be passed through the process chamber 223.

Once the fixed volume of the rinse fluid 50 is supplied to the stand-alone rinse tool 1000, a batch of substrates 75 comprising ionic impurities are positioned within the rinse chamber 223 of the rinse tank 220. The pump 260 is then activated, thereby forcing the rinse fluid 50 that is in the recirculation line 240 into the rinse tank 220 where it contacts the substrates 75 as the spray 51. Upon contacting the substrates 75, the rinse fluid 50 removes ionic impurities (and other contaminants) from the substrates 75 and carries these ionic impurities away from the substrates 75 and into the rinse fluid 50 that forms the bath at the bottom of the rinse chamber 223. The rinse fluid 50 that forms the bath at the bottom of the rinse chamber 223 is, thus, ionically contaminated rinse fluid 50.

As the pump 260 continues to operate, the ionically contaminated rinse fluid 50 from the bath flows through the deionizer 280. As the ionically contaminated rinse fluid 50 flows through the deionizer, the deionizer 280 removes the ionic impurities, thereby outputting an effluent of deionized rinse fluid 50. This effluent of deionized rinse fluid 50 is then fed back into the recirculation line 240 where it is again introduced back into the rinse tank 220 for further contact and cleaning of the substrates 75 as the spray 51.

For each rinse cycle, the above circulation of the fixed volume of the rinse fluid 50 through the closed-loop fluid circuit 200 is performed for a rinse cycle time (wherein a different batch of substrates 70 is cleaned during each rinse cycle). The rinse cycle time is a time sufficient to ensure that the ionic impurities on the substrates 75 of the batch has been adequately removed/reduced to acceptable levels for further processing. In one embodiment, the rinse cycle time can be a predetermined period of time that is stored in the memory device 303 (or a timer) and executed by the controller 301. In other embodiments, the rinse cycle time can be a non-established period of time, the end of which is determined by the ionic impurity levels measured by the ionic impurity level sensor 302 reaching an acceptably low threshold. In such an embodiment, a predetermined ionic impurity level (i.e. a lower threshold) that is indicative that the substrates 75 have been adequately cleaned is stored in the memory device 303. The controller 301 will receive, from the ionic impurity level sensor 302, signals indicative of the measured ionic impurity levels and compare these measured levels to the predetermined (and stored) ionic impurity level that is indicative that the substrates 75 are clean. Upon the controller 301 determining that the measured ionic impurity level is at or below the predetermined ionic impurity level that is indicative of the substrates 75 being clean, the controller 301 will end the rinse cycle, thereby establishing the rinse cycle time “on the fly” or post hoc.

As should be apparent form above, during each rinse cycle, the fixed volume of the rinse fluid 50 can be turned-over multiple times through the rinse tank 220. Thus, despite the fixed volume of the rinse fluid 50 being a fraction of that which is needed to perform a rinse cycle, the rinse cycle can be completed due to the self-cleaning performed by the deionizer 280. Once a rinse cycle is complete for a specific batch of substrates 75, the substrates 75 are removed from the rinse tank 220. The same fixed volume of the rinse fluid 50 is then used consecutively for an unlimited number of rinse cycles, each rinse cycle cleaning a different batch of substrates 75.

As set forth above, the fixed volume of the rinse fluid 50 stays in the stand-alone rinse tool 1000 (and more specifically stays within the point-of-use closed-loop fluid circuit 200) during the performance of the rinse cycles. The fixed amount of the rinse fluid 50 is never sent to a central reclaim station of the fabrication facility either during a rinsing cycle or between the rinsing cycles. Moreover, the plurality of rinse cycles are performed without rinse fluid 50 being added to the closed-loop fluid circuit 200 beyond the initial fixed volume of rinse fluid 200 that is supplied at start-up. As mentioned above, however, minimal amounts of additional rinse fluid may be added to compensate for drag out and evaporative loss. This would be the only amounts of additional rinse fluid added to the closed-loop fluid circuit 200 in addition to the initial start-up fixed volume. Thus, the stand-alone rinse tool 1000 can perform a plurality of rinse cycles that results in substantially zero rinse fluid consumption. In this manner, the stand-alone rinse tool 1000 is self-contained, self-sustained and self-cleaning.

As also mentioned above, the only requirement is that the deionizer 280 be replaced as necessary once it becomes saturated. Saturation of the deionizer 280 can be detected by the controller 301 through comparison of the measured ionic impurity levels received by the sensor 302 with a predetermined impurity level threshold stored in the memory device 303. Upon the controller 301 determining that the measured ionic impurity level is at or above the predetermined impurity level threshold, the controller 301 will signal the user that the deionizer 280 needs to be replaced. Alternatively, the controller 301 can simply monitor for a major spike or a flat-line above a minimum in the measured ionic impurity levels.

Finally, while the invention is exemplified herein as only using a deionizer 280 to filter the rinse fluid 50, in certain embodiments the stand-alone rinse tool 1000 will also comprise additional filtration mechanisms, such as a particle filter. In such an embodiment, the particle filter would be part of the closed-loop fluid circuit 200 and be operably and fluidly coupled to recirculation line 240 at a position downstream of the point at which the rinse fluid 50 contacts the substrates 75. In certain embodiments, the particle filter may be upstream of the deionizer 280 to prevent blocking/clogging of the deionizer 280 with particulate matter.

The particle filter removes both positively and negatively charged particles (i.e., contaminants) from the rinse fluid passing through. The particle filter incorporates at least one positively charged filter media and one negatively charged filter media in series. The filter media are constructed so as to have a positive charge and/or negative charge respectively. Thus, an electrical charge does not have to be applied to the filter media during use to capture particles. In another embodiment, the particle filter can contain a single filter media that can remove both negatively and positively charged particles. The filter media have a pore rating of 0.01 .mu.m. However, filters having different pore ratings can be used depending on processing cleanliness requirements.

Similar to the deionizer 80, a control scheme to detect when the particle filter needs to be replaced can be implemented using the controller 302 and a particle count sensor, such as a liquid-borne particle counter, such as those made by Particle Measuring Systems (PMS), models Ultra DI or HSLIS, Liquistat, CLS700, or CLS1000. The measuring technique used by the liquid-borne particle counter uses a laser scattering technique wherein a laser beam shines through the rinse fluid, and once a particle passes by, the light is scattered and the scattering pattern determines the size of the particle.

While the invention has been described with respect to specific examples including presently preferred modes of carrying out the invention, those skilled in the art will appreciate that there are numerous variations and permutations of the above described systems and techniques. It is to be understood that other embodiments may be utilized and structural and functional modifications may be made without departing from the scope of the present invention. Thus, the spirit and scope of the invention should be construed broadly as set forth in the appended claims.

1. A method of rinsing substrates comprising:
a) providing a fixed volume of a rinse fluid in a stand-alone rinse tool comprising a closed-loop fluid-circuit comprising a rinse tank, a deionizer, a pump, and a recirculation line fluidly coupled to an outlet of the rinse tank and an inlet of the rinse tank; and
b) performing a plurality of rinse cycles in the stand-alone rinse tool using the fixed volume of the rinse fluid, wherein each of the plurality of rinse cycles comprises:
b-1) positioning a batch of substrates comprising ionic impurities in the rinse tank;
b-2) circulating the fixed volume of the rinse fluid provided in step a) through the closed-loop fluid circuit for a rinse time sufficient to remove the ionic impurities from the batch of substrates, wherein during said circulation the rinse fluid contacts the batch of substrates, thereby becoming ionically contaminated rinse fluid that flows through the deionizer, the deionizer removing ionic impurities from the ionically contaminated rinse fluid to produce deionized rinse fluid that is introduced back into the rinse tank; and
b-3) removing the batch of substrates from the rinse tank upon expiration of the rinse time.

2. The method of claim 1 wherein step b) is performed without rinse fluid being added to the closed-loop fluid circuit beyond the fixed volume of rinse fluid supplied in step b).

3. The method of claim 1 wherein the rinse fluid is deionized water.

4. The method of claim 1 further comprising a controller and a sensor for measuring ionic impurity levels in the rinse fluid, the method further comprising:
repetitively measuring ionic impurity levels in the purified rinse fluid with the sensor; and
upon determining that the measured ionic impurity level is at or above a predetermined threshold, the controller signaling a user that the deionizer needs to be replaced.

5. The method of claim 1 wherein the deionizer is a mixed resin bed located either within the rinse tank or adjacent the drain.

6. (canceled)

7. The method of claim 1 wherein the stand-alone rinse tool comprises a housing, a substantial entirety of the closed-loop fluid circuit located within the housing.

8. The method of claim 1 further comprising:
prior to step b), determining a number (N) of the rinse cycles that can be performed before the deionizer becomes saturated and storing said number (N) in a memory device;
counting the rinse cycles performed in step b) using a counter; and
upon the N^{th} rinse cycle being counted as having been performed in step b), generating a signal that the deionizer needs to be replaced.

9. The method of claim 8 wherein upon the deionizer being replaced, setting the counter to zero and performing step b) again using the fixed amount of the rinse fluid provided in step a).

10. The method of claim 8 wherein the number (N) of the rinse cycles that can be performed before the deionizer becomes saturated is determined experimentally.

11. The method of claim 8 wherein the number (N) of the rinse cycles that can be performed before the deionizer becomes saturated is determined by: estimating an average amount of ionic impurities dragged from a prior process by a batch of substrates that is to be subjected to one of the rinse cycles; and estimating an ionic impurity saturation amount of the deionizer.

12. The method of claim 1 wherein the stand-alone rinse tool is free of a holding tank containing additional rinse fluid.

13. The method of claim 1 wherein all of the rinse fluid used in step b) is recirculated rinse fluid that is contained within the stand-alone rinse tool.

14. The method of claim 1 wherein the rinse fluid does not flow to a centralized rinse fluid reclaim station of the fabrication facility.

15. The method of claim 1 wherein step b) results in substantially zero rinse fluid consumption.

16. (canceled)

17. (canceled)

18. The method of claim 1 wherein the fixed volume of the rinse fluid stays in the closed-loop fluid circuit during step b), a substantial entirety of the closed-loop fluid circuit being contained within the stand-alone rinse tool.

19. The method of claim 1 wherein the closed-loop fluid circuit comprises a free volume that is substantially the same as the fixed volume of the rinse fluid.

20. The method of claim 1 wherein subsequent to the initial supply of the fixed volume of the rinse fluid in step a), step b) can be performed for an unlimited number of rinse cycles with substantially zero rinse fluid consumption.

21.-30. (canceled)

31. A method of rinsing substrates comprising:
a) providing a stand-alone rinse tool comprising a closed-loop fluid-circuit comprising a rinse tank, a deionizer, a pump, and a recirculation line fluidly coupled to an outlet of the rinse tank and an inlet of the rinse tank;
b) during an initial set-up procedure, supplying a fixed volume of a rinse fluid into the closed-loop fluid circuit; and
c) performing a plurality of rinse cycles in the stand-alone rinse tool using the fixed volume of the rinse fluid, wherein each of the plurality of rinse cycles comprises:
c-1) positioning a batch of substrates comprising ionic impurities in the rinse tank;
c-2) circulating the fixed volume of the rinse fluid provided in step b) through the closed-loop fluid circuit for a rinse time sufficient to remove the ionic impurities from the batch of substrates, wherein during said circulation the rinse fluid contacts the batch of substrates, thereby becoming ionically contaminated rinse fluid that flows through the deionizer, the deionizer removing ionic impurities from the ionically contaminated rinse fluid to produce deionized rinse fluid that is introduced back into the rinse tank; and
c-3) removing the batch of substrates from the rinse tank upon expiration of the rinse time;
wherein subsequent to step b), substantially no additional rinse fluid is introduced into the closed-loop fluid circuit.

31a. (canceled)

32. The method of claim 31 wherein step c) is performed using only the fixed volume of the rinse fluid provided in step b).

33. The method of claim 31 wherein the closed-loop fluid circuit is self-contained within the stand-alone rinse tool.
